(19) United States
(12) Patent Application Publication
(10) Pub. No.: US 2005/0224953 A1
(43) Pub. Date: Oct. 13, 2005

(54) Heat spreader lid cavity filled with cured molding compound

(76) Inventors: Michael Keat Lye Lee, Petaling Jaya (MY); Poh Kheng Tang, Penang (MY); Lisa Yung Hui Lee, Sibu (MY)

Correspondence Address: SCHWABE, WILLIAMSON & WYATT, P.C.;PACWEST CENTER, SUITE 1900, 1211 SW FIFTH AVENUE, PORTLAND, OR, 97204, US

(21) Appl. No.: 10/804,903

(22) Filed: Mar. 19, 2004

(51) Int. Cl. H01L 21/48; H01L 23/52

(52) U.S. Cl. 257/704; 438/125

(57) ABSTRACT

An apparatus which comprises a die carrier; a heat spreader lid mounted on the die carrier to form a lid cavity; an integrated circuit (IC) die mounted on the die carrier and within the lid cavity; and a cured mold compound disposed to fill the lid cavity and to partially surround the IC die.

### BACKGROUND OF THE INVENTION

1. Field of the Invention

The present invention relates to electronic devices, and in particular, to packaging of electronic devices.

2. Description of Related Art

FIG. 1 shows an Integrated Circuit (IC) package 10 using a prior art approach for mounting an IC die 12 in the IC package 10. The IC package 10 includes a substrate or die carrier 14 with the IC die 12 mounted thereon by use of an underfill 16. The underfill 16 extends along the bottom and edges of the IC die 12. An Integrated Heat Spreader (IHS) lid 18 is mounted to the die carrier 14 by use of a sealant 20, with a Thermal Interface Material (TIM) 22 being interposed between the IC die 12 and the IHS lid 18 for heat removal. The IHS lid 18 forms a lid cavity 19, which is mostly filled with air. The electrical interconnections between the IC die 12 and the die carrier 14 are accomplished by a plurality of die solder bumps 24. The electrical interconnections between the die carrier 14 and a printed circuit board (not shown) are accomplished by an array of solder balls 26. Although the package 10 is shown as a Ball-Grid-Array (BGA) package, other package designs may utilize this prior art combination of die attachment with IHS lid, such as a Pin-Grid-Array (PGA) package.

IC packages, such as the IC package 10, may go through many process steps during IC package assembly that involve elevated temperatures, such as chip attachment reflow, deflux, epoxy underfill prebake/cure, integrated heat spreader cure, and ball attachment reflow. These processes and others may contribute to package warpage. This warpage is shown in a simplified diagram of FIG. 2, wherein the package 10 is shown with the die carrier 14 being warped so as to have convex cross-sectional profile. Such package warpage may generate many issues, such as low-k Interlayer Dielectric (ILD) die cracks, out-of-specification coplanarity, and unevenly distributed thermal heat dissipation.

With respect to the low-k ILD die crack issue, current 90 nm wafer technology for IC dice may use a low-k dielectric layer (porous cured dielectric) in its built up layer. Use of this dielectric layer imposes the need to have reduced stress on the die, such as stress caused by package warpage. Die stress cracks and die bump cracks have increased with current IC packages adopting this low-k ILD dialectric layer usage. These cracks in turn may create multiple reliability issues for the IC package, such as open circuit failures, short circuit failures, reliability stress failures, and ultimately component dysfunctional failures.

With respect to the out-of-specification coplanarity issue, excessive outgoing package warpage after packaging assembly processes has been increasing with more complicated and larger IC packages. Recently, large packages with smaller dies have been found to have warpages creating high deviations from the desired within-specification coplanarity, i.e., desired flatness. Such warpage of the IC package may create many problems for downstream users of the package. For Pin Grid Array (PGA) packages, it may contribute to poor pin tip positioning that leads to pin rework. For Ball Grid Array (BGA) packages, excessive warpage may lead to surface-mount issues. For Land Grid Array (LGA) packages, package warpage may lead to high resistance or open contacts between the IC package and a socket.

With respect to the unevenly distributed thermal heat dissipation issue, thermal heat dissipation has become an obstacle with increasing speed in IC packages. Slight out-of-specifications for IHS lid tilt in IC packages may cause imbalanced distribution of heat along the die surface and die edge. Uneven or limited thermal distribution may lead to thermal failures of the IC package.

Molding has been used in prior art IC packages without IHS lids. In IC packages where wire bonding is used to couple the die to the die carrier, molding has been used to freeze the wire loops so that wire problems do not occur. In some types of IC packaging, molding also has been used to control coplanarity.

### BRIEF DESCRIPTION OF THE DRAWINGS

FIG. 1 is a diagram of a prior art IC package.

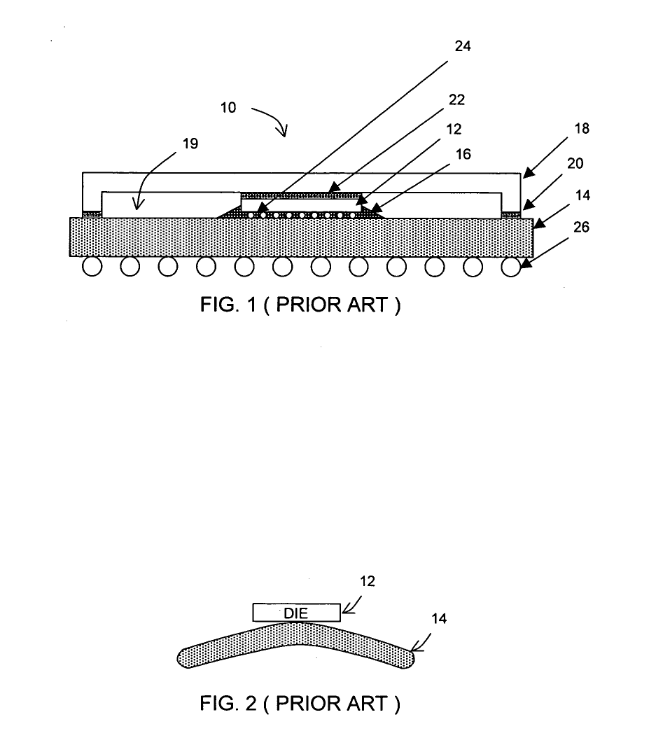

FIG. 2 is a simplified diagram of the prior art package of FIG. 1 which illustrates package warpage.

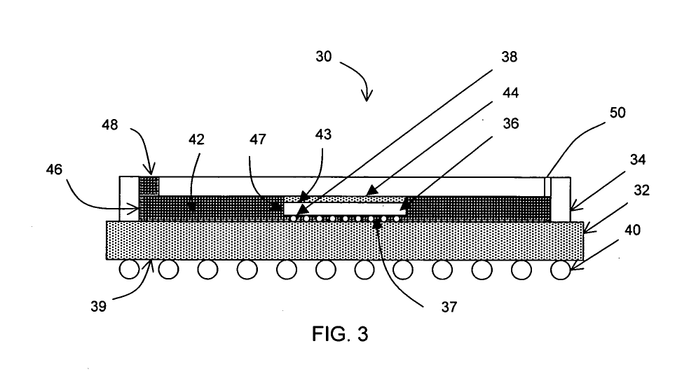

FIG. 3 is a diagram of an IC package in accordance with one embodiment of the present invention.

FIG. 4 is a flow chart of a process of assembling the IC package of FIG. 3, in accordance with one method of the present invention.

FIGS. 5A through 5E show various phases of the IC package of FIG. 3 as it progresses through the assembly process of FIG. 4 in accordance with one method of the present invention.

FIG. 6 shows a block diagram of a system incorporating the IC package of FIG. 3 in accordance with one embodiment of the present invention.

### DETAILED DESCRIPTION OF ILLUSTRATIVE EMBODIMENTS

In the following description, for purposes of explanation, numerous details are set forth in order to provide a thorough understanding of the disclosed embodiments of the present invention. However, it will be apparent to one skilled in the art that these specific details are not required in order to practice the disclosed embodiments of the present invention. In other instances, well-known electrical structures and circuits are shown in block diagram form in order not to obscure the disclosed embodiments of the present invention.

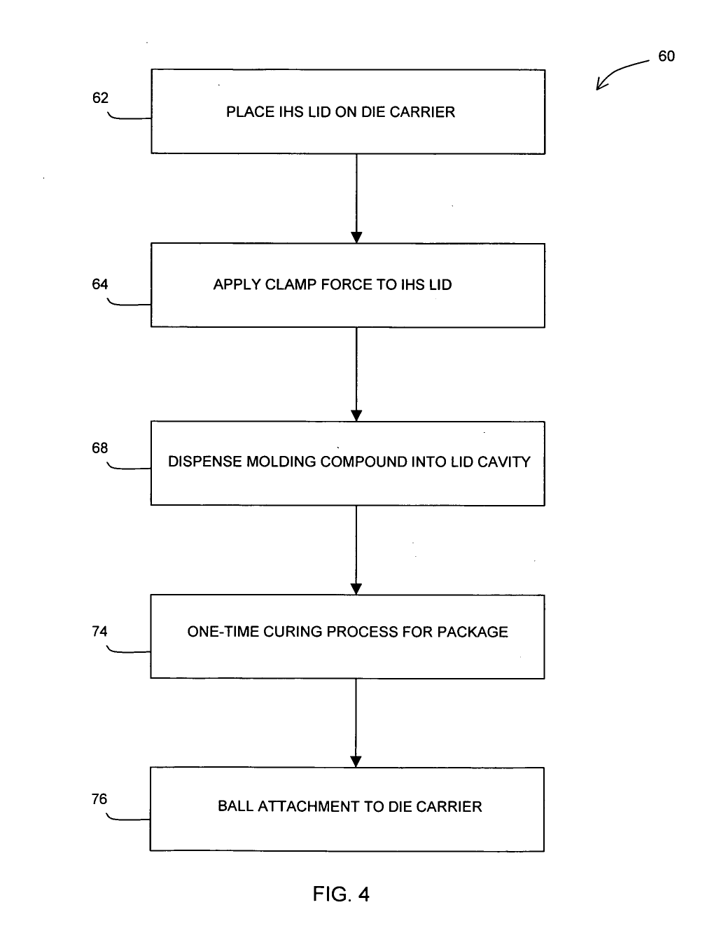

FIG. 3 shows an Integrated Circuit (IC) package 30 in accordance with one embodiment of the present invention. Merely for the purposes of illustration, the IC package 30 is shown as a Ball-Grid-Array (BGA) package. The IC package 30 includes a die carrier 32, an Integrated Heat Spreader (IHS) lid 34 and an IC chip or die 36, with the die 36 being interposed between the die carrier 32 and the heat spreader lid 34. The heat spreader lid 34 may be formed of metal to assist in heat dissipation. The die 36 may have a bottom or first surface 37 with a plurality of bond pads (not shown). The electrical interconnections between the bond pads of die 36 and a plurality of die-side pads (not shown) on the die carrier 32 may be accomplished by a plurality of die solder bumps 38. The electrical interconnections between a plurality of electrical contacts (not shown) on a land side 39 of the die carrier 32 and a plurality of board contacts (not shown) on a printed circuit board (not shown) may accomplished by an array electrical connections, such as a plurality of solder balls 40.

Between the heat spreader lid 34 and the die carrier 32 a lid cavity 42 is formed. A cold form Thermal Interface Material (TIM) 44, along with the die 36, may be positioned in the lid cavity 42. More specifically, the cold form TIM 44 may be interposed between and in contact with a top or second surface 43 of the die 36 and the heat spreader lid 34 to dissipate heat from the die 36 through the IHS lid 34. The cold form TIM 44 may be positioned and aligned on the center axes for the IC package 30 and the die 36 and also may match the size (i.e., width and length) of the die 36.

A portion of the lid cavity 42 not occupied by the die 36 and the cold form TIM 44 is filled with a mold compound 46. The heat spreader lid 34 may have a dispensing hole 48 (e.g., circular aperture, slit or slot) for injecting the mold compound 46 into the lid cavity 42 and an air outlet hole 50 (i.e., vent) for releasing air while the mold compound is being injected into the lid cavity 42. The heat spreader lid 34 may act as a metal mold for the mold compound 46, a stiffener for the IC package 30, and a heat spreader for the die 36. The mold compound 46 may be a polymeric material, which may act as an underfill for the die 36, a second level thermal interface material (the cold form TIM 44 being the first), and a sealant for securing the heat spreader lid 34 to the die carrier 32. The polymeric material of the mold compound 46 may be an organic compound material with epoxy properties and with a chemical structure including carbon, hydrogen, and oxygen.

The first surface 37 and a plurality of lateral sides 47 of the die 36 are encapsulated by the mold compound 46. The lateral sides 47 extend between the opposed first and second surfaces 37 and 43 of the die 36. Additionally, the mold compound 46 is fused with the heat spreader lid 34 and the die carrier 32. The mold compound 46, heat spreader lid 34, die carrier 32, and die 36 are fused into a one piece, solid structure by a one-time curing process to be described hereinafter. This fusion into a solid structure may cause stress to be distributed evenly throughout the die 36, mold compound 46, die carrier 32 and heat spreader lid 34. The polymeric property of the mold compound 46 may provide a cushioning effect for the die 36.

Consequently, this one piece, solid structure of the IC package 30 may prevent any excessive stress from being induced solely on the die 36, thus preventing low-k ILD die cracks. Additionally, excessive deviation from the desired coplanarity in large packages with a small dice, such as the IC package 30, may be reduced by having such a solid structure. Low package warpage may assist in the IC package 30 being comply to JEDEC (Joint Electronic Device Engineering Council) standards, thus enabling higher yield and lower outgoing rejects. Furthermore, the thermal performance of the IC package 30 may be increased and heat dissipated more evenly through the mold compound 46 by including conductive fillers in the mold compound 46. Conductive fillers may be either solidification or liquidous materials with thermal conductive properties. Solid fillers may include aluminum or any metal having good mixing interactions with the polymeric materials. The liquidous/coloidal fillers may include silicone oil or any aqueous filler with silicon as the main component in its chemical structures. The thermal performance may be increased due to the evenly spread mold compound 46 encapsulating the die 36. Also, the IC package 30 may enable higher thermal heat dissipation in part by ensuring lower tilts for heat spreader lid 34. Lower lid tilt also may directly translate to lower yield loss.

It may be particularly desirable to control package warpage, in order to avoid low-k ILD cracking, coplanarity fallouts, and thermal issues, with processor and chipset packages using Flip Chip (FC) mounting for dice, such as in Flip Chip Ball Grid Array (FCBGA) packages, as shown in FIG. 3, and to Flip Chip Pin Grid Array (FCPGA) packages. In FCPGA packages, pins are used in place of land pads and solder balls for mounting the package to a printed circuit board. In the fabrication the IC package 30, flip-chip mounting is used, i.e., the die 36 is flipped upside down and attached directly to the die carrier 32 using the die solder bumps 38. In this manner, bond pads (not shown) on the die 36 may be placed at any position of the die 36, instead of making all the electrical interconnections on the boundary of the die 36.

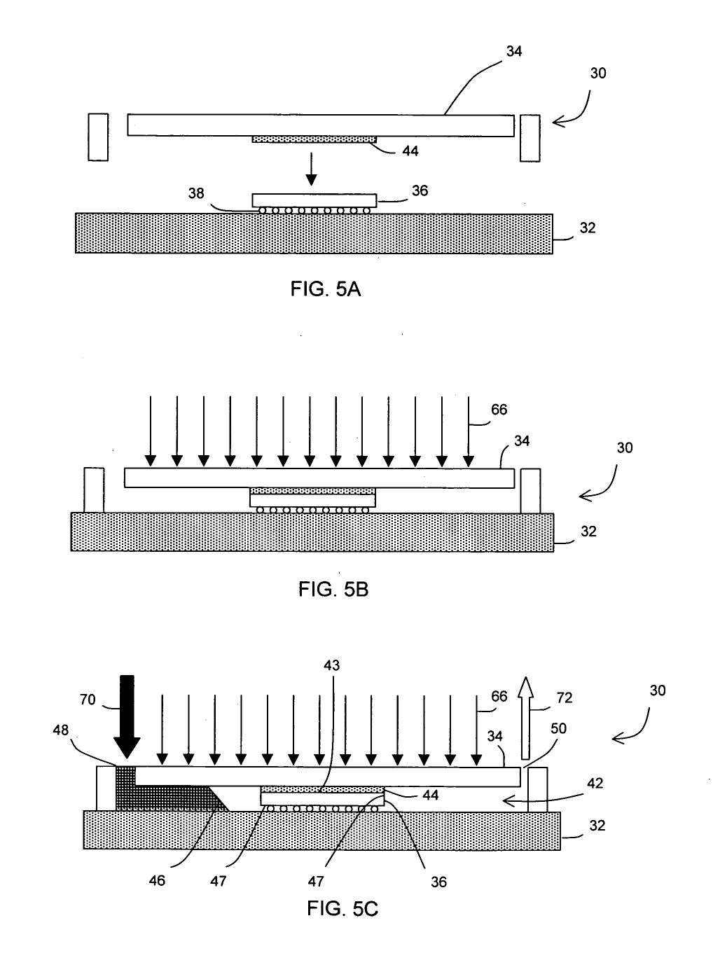

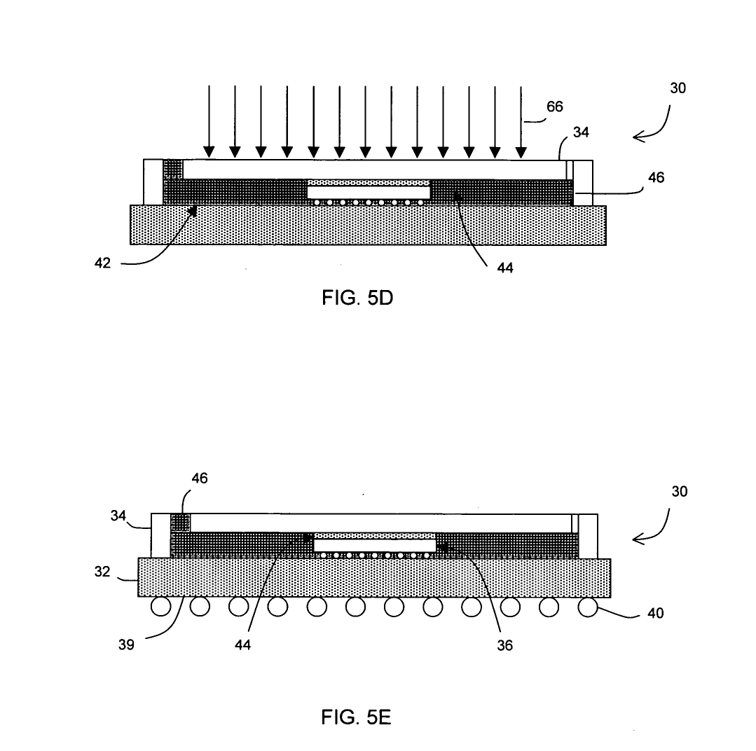

With respect to FIGS. 3.and 4, the IC package 30 may be fabricated using an assembly process 60. The assembly process 60 includes a molding process which is performed within the heat spreader lid 34. This assembly process 60 may assist in achieving the previously described desirable results of preventing or reducing low-k ILD cracks, excessive package warpage/out-of-specification coplanarity, and unevenly distributed thermal heat dissipation in the IC package 30. Details of the assembly process 60 are described with reference to the flow chart of in FIG. 4, in combination with FIGS. 5A through 5E which show the stages of development of the IC package 30 as it passes through the assembly process 60.

Referring to FIGS. 4 and 5A, at a block 62 of the assembly process 60, the heat spreader lid 34 is placed on top of the die carrier 32 after a die attachment process, e.g., the previously-described flip-chip mounting process wherein the die 36 is flipped upside down and attached directly to the die carrier 32 using the die solder bumps 38. The heat spreader lid 34 is a stamped metal lid. Prior to the heat spreader lid 34 being placed on the die carrier 32, the cold form TIM 44 is attached to the heat spreader lid 34.

Referring to FIGS. 4 and 5B, at a block 64 of the assembly process 60, a clamping force, shown by force vectors 66, is applied to the upper surface of the heat spreader lid 34. More specifically, once the heat spreader lid 34 is placed on top of the die carrier 32, the clamping force may be downwardly applied to the top of the lid 34 so as to ensure that the lid 34 is pressed onto the die carrier 32 during the dispensing of the mold compound and a subsequent curing process. The clamping force may be induced by metal clip (not shown) attached to a support (not shown) on which the die carrier 32 is mounted. The clamping force may also be induced by a clamping mechanism included with a metal chassis that is part of commonly used mold dispensing equipment.

Referring to FIGS. 4 and 5C, at a block 68 of the assembly process 60, the mold compound 46 is dispensed into the lid cavity 42 as shown by an arrow 70. As the mold compound is dispensed or injected into lid cavity 42, air from the cavity 42 escapes through the air outlet hole 50 as shown by an arrow 72. The mold compound 46 may act as a sealant material to attach the lid 34 to the die carrier 32, as an underfill material positioned under the first surface 37 of the die 36 and also as a secondary Thermal Interface Material (TIM). The secondary TIM aspect of the molding compound 46 may help to dissipate heat from the lateral sides 47 of the die 36, in addition to the heat dissipation from the second surface 43 of the die 36 through the cold form TIM 44. The clamping force 66 may remain applied to the lid 34 during the dispensing of the mold compound 46.

Referring to FIGS. 4 and 5D, at a block 74 of the assembly process 60, the package 30 is subjected to a one-time curing process. More specifically, once the mold compound 46 fully fills the lid cavity 42, the IC package 30 may be delivered to curing equipment for implementing the curing process. This particular curing process may cure both the cold form TIM 44 and the material of the mold compound 46 at the same time. Curing both at the same time may minimize manufacturing time and reduces multiple cure/reflow activities. The clamping force 66 may remain applied to the lid 34 during the curing process.

Referring to FIGS. 4 and 5E, at a block 76 of the assembly process 60, the clamping force may be removed after curing process. At this point, a solid state has been produced for the die carrier 32, die 36, cold form TIM 44, mold compound 46, and heat spreader lid 34. The IC package 30 now may be subjected to a ball attachment process, wherein the solder balls 40 may be attached to land pads (not shown) on the underside or land side 39 of the die carrier 32. The final IC package 30 may have lower package warpage and stiffer layers. This assembly process 60 may prevent low-k iLD cracks, out-of-specification coplanarity, and unevenly distributed thermal heat dissipation.

With respect to FIGS. 4 and 5A-5E, the combination of utilizing both the lid 34 and the mold compound 46 may control the package state so as to maintain a flat shape of the IC package 30, while also fulfilling the thermal requirements of the IC package 30. This combination may resolve both low-k iLD die cracks and also out-of-specification coplanarity of large packages with small dice. In summary, this assembly process 60 serves to eliminate low-k iLD stress cracks and die bump cracks, control package coplanarity especially for large packages with small die, improve thermal performances, and strengthen the IC package 30 as a whole.

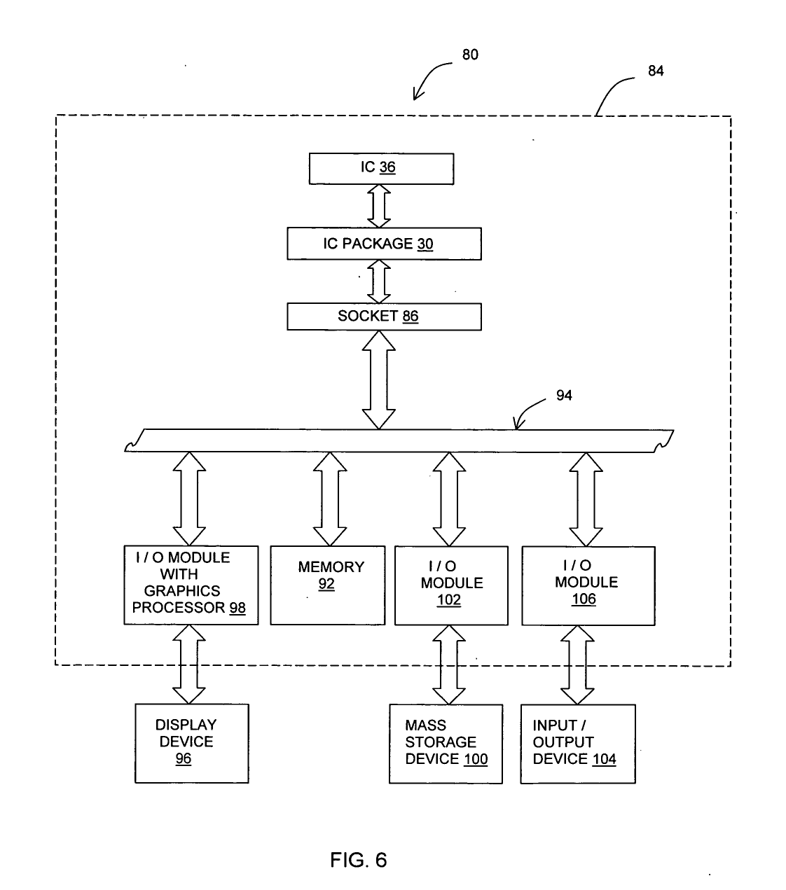

Referring to FIG. 6, there is illustrated a system 80, which is one of many possible systems in which the IC package 30 of FIG. 3 may be used. In the system 80 the IC package is mounted on a substrate or printed circuit board (PCB) 84 via a socket 86. The IC die 36 of the IC package 30 may be a processor and the PCB 84 may be a motherboard. However, in other systems the IC package 30 may be directly coupled to the PCB 84 (eliminating the socket 86 which allows the IC package 30 to be removable). In addition to the socket 86 and the IC package 30, the PCB 84 may have mounted thereon a main memory 92 and a plurality of input/output (I/O) modules for external devices or external buses, all coupled to each other by a bus system 94 on the PCB 84. More specifically, the system 80 may include a display device 96 coupled to the bus system 94 by way of an I/O module 98, with the I/O module 98 having a graphical processor and a memory. The I/O module 98 may be mounted on the PCB 84 as shown in FIG. 6 or may be mounted on a separate expansion board. The system 80 may further include a mass storage device 100 coupled to the bus system 94 via an I/O module 102. Another I/O device 104 may be coupled to the bus system 94 via an I/O module 106. Additional I/O modules may be included for other external or peripheral devices or external buses.

Examples of the main memory 92 include, but are not limited to, static random access memory (SRAM) and dynamic random access memory (DRAM). The memory 92 may include an additional cache memory. Examples of the mass storage device 100 include, but are not limited to, a hard disk drive, a compact disk drive (CD), a digital versatile disk driver (DVD), a floppy diskette, a tape system and so forth. Examples of the input/output devices 104 may include, but are not limited to, devices suitable for communication with a computer user (e.g., a keyboard, cursor control devices, microphone, a voice recognition device, a display, a printer, speakers, and a scanner) and devices suitable for communications with remote devices over communication networks (e.g., Ethernet interface device, analog and digital modems, ISDN terminal adapters, and frame relay devices). In some cases, these communications devices may also be mounted on the PCB 84. Examples of the bus system 94 include, but are not limited to, a peripheral control interface (PCI) bus, and Industry Standard Architecture (ISA) bus, and so forth. The bus system 94 may be implemented as a single bus or as a combination of buses (e.g., system bus with expansion buses). Depending upon the external device, I/O modules internal interfaces may use programmed I/O, interrupt-driven I/O, or direct memory access (DMA) techniques for communications over the bus system 94. Depending upon the external device, external interfaces of the I/O modules may provide to the external device(s) a point-to point parallel interface (e.g., Small Computer System Interface—SCSI) or point-to-point serial interface (e.g., EIA-232) or a multipoint serial interface (e.g., FireWire). Examples of the IC die 36 may include any type of computational circuit such as, but not limited to, a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), or any other type of processor or processing circuit.

In various embodiments, the system 80 may be a wireless mobile or cellular phone, a pager, a portable phone, a one-way or two-way radio, a personal digital assistant, a pocket PC, a tablet PC, a notebook PC, a desktop computer, a set-top box, an entertainment unit, a DVD player, a server, a medical device, an internet appliance and so forth.

Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the present invention. Therefore, it is manifestly intended that this invention be limited only by the claims and the equivalents thereof.

1. An apparatus, comprising:
a die carrier;
a heat spreader lid mounted on the die carrier to form a lid cavity;
an integrated circuit (IC) die mounted on the die carrier and within the lid cavity; and
a cured mold compound disposed to fill the lid cavity and to at least partially surround the IC die.

2. The apparatus according to claim 1, wherein the heat spreader lid has a dispensing hole formed therein to facilitate injection of a mold compound solution into the lid cavity and an air outlet hole formed therein to allow air to escape from the lid cavity.

3. The apparatus according to claim 2, wherein heat spreader lid is made of metal.

4. The apparatus according to claim 3, wherein the heat spreader lid includes a thermal interface material interposed in thermal conducting relationship between the heat spreader lid and the die.

5. The apparatus according to claim 4, wherein the thermal interface material is coaxially aligned with the die and includes a width and a length dimension which are substantially the same as a corresponding width and a corresponding length dimension of the die.

6. The apparatus according to claim 5, wherein the thermal interface material comprises a cold form thermal interface material.

7. The apparatus according to claim 6, wherein the die includes a first surface, a second surface and a plurality of lateral sides extending between the first and second surfaces; the first surface includes a plurality of electrical contacts coupled to the die carrier; the second surface is disposed in an abutting relationship with the thermal interface material; and the mold compound extends between the heat spreader lid and the die carrier and surrounds the lateral sides and the first surface of the die.

8. The apparatus according to claim 7, wherein the die is mounted to the die carrier by a flip-chip mounting.

9. The apparatus according to claim 8, wherein the flip-chip mounting includes a plurality of solder bumps coupling the die to the die carrier.

10. The apparatus according to claim 10, wherein the mold compound is a polymeric material.

11. A method, comprising
providing a die carrier with a die mounted thereon and a heat spreader lid with a thermal interface material mounted thereon for use in forming a package;
forming the package by placing the heat spreader lid on the die carrier to form a lid cavity therebetween;
dispensing a mold compound into the lid cavity; and
curing the package.

12. The method according to claim 11, wherein dispensing the mold compound into the lid cavity includes dispensing the mold compound through a dispensing hole formed in the heat spreader lid and allowing air to escape through an air outlet hole in the lid cavity.

13. The method according to claim 12, wherein curing the package includes a one-time curing of both the mold compound and the thermal interface material.

14. The method according to claim 13, further comprising:
applying a clamping force to the heat spreader lid during the dispensing of the mold compound and the curing of the package.

15. The method according to claim 14, further comprising:
after the curing process, removing the clamping force and mounting a plurality of electrical contacts to the land side of the die carrier.

16. A system, comprising:
an integrated circuit (IC) package including a die carrier; a heat spreader lid mounted on the die carrier to form a lid cavity; an IC die mounted on the die carrier and within the lid cavity; and a cured mold compound disposed to fill the lid cavity and to partially surround the IC die; and
a circuit board having mounted thereon the IC package; a dynamic random access memory coupled to the IC package; and an input/output interface coupled to the IC package.

17. The system according to claim 16, wherein the IC die is a microprocessor and the circuit board is a motherboard.

18. The system according to claim 17, wherein the input/output interface comprises a networking interface.

19. The system according to claim 18, wherein the system is a selected one of a set-top box, an entertainment unit and a DVD player.

20. The system according to claim 16, wherein the heat spreader lid has a dispensing hole formed therein to inject a mold compound solution into the lid cavity and an air outlet hole formed therein to allow air to escape from the lid cavity.

21. The system according to claim 20, wherein heat spreader lid is made of metal.

22. The system according to claim 21, wherein the heat spreader lid includes a thermal interface material interposed in thermal conducting relationship between the heat spreader lid and the die.

23. The system according to claim 22, wherein the thermal interface material is coaxially aligned with the die and includes a width and a length dimension which are substantially the same as a corresponding width and a corresponding length dimension of the die.

24. The system according to claim 23, wherein the thermal interface material comprises a cold form thermal interface material.

25. The system according to claim 24, wherein the die includes a first surface, a second surface and a plurality of lateral sides extending between the first and second surfaces; the first surface includes a plurality of electrical contacts coupled to the die carrier; the second surface is disposed in an abutting relationship with the thermal interface material; and the mold compound extends between the heat spreader lid and the die carrier and surrounds the lateral sides and the first surface of the die.

26. The system according to claim 25, wherein the die is mounted to the die carrier by a flip-chip mounting.

27. The system according to claim 26, wherein the flip-chip mounting includes a plurality of solder bumps coupling the die to the die carrier.

28. The system according to claim 27, wherein the mold compound is a polymeric material.
